(19) United States
(12) Patent Application Publication
(10) Pub. No.: US 2026/0322096 A1
(43) Pub. Date: Oct. 15, 2026

(54) HARNESS HEAT DISSIPATION STRUCTURE

(71) Applicant: Yazaki Corporation, Tokyo (JP)

(72) Inventor: Hiroaki ITO, Shizuoka (JP)

(73) Assignee: Yazaki Corporation, Tokyo (JP)

(21) Appl. No.: 19/681,834

(22) Filed: May 19, 2026

Related U.S. Application Data
(63) Continuation of application No. PCT/JP2024/041450, filed on Nov. 22, 2024.

(30) Foreign Application Priority Data
Dec. 18, 2023 (JP) 2023-213079

(51) Int. Cl. H02G 5/10; B60R 16/02; H02G 3/30

(52) U.S. Cl. CPC H02G 5/10; B60R 16/0215; H02G 3/30

(57) ABSTRACT

A harness heat dissipation structure includes a wire harness that is routed on a vehicle body of a vehicle, and a pressing member that presses the wire harness against the vehicle body. The wire harness includes a plate-shaped conductor having electric conductivity, and the plate-shaped conductor has a rectangular cross-sectional shape in a direction orthogonal to a routing direction of the wire harness. The vehicle body includes a thick portion that is formed thicker than surrounding portions at a location where the pressing member is attached and where the plate-shaped conductor of the wire harness is pressed by the pressing member.

### CROSS-REFERENCE TO RELATED APPLICATIONS

The present application is a continuation of International Application No. PCT/JP2024/041450, filed on Nov. 22, 2024, and based upon and claims the benefit of priority from Japanese Patent Application No. 2023-213079, filed on Dec. 18, 2023, the entire contents of which are incorporated herein by reference.

### TECHNICAL FIELD

The disclosure relates to a harness heat dissipation structure.

### BACKGROUND

JP 2020-21556 A discloses a technique relating to a wire harness that is used in a vehicle such as an electric vehicle or a plug-in hybrid vehicle and that includes electric wires for electrically connecting a high-voltage battery and an electric device such as an inverter. The wire harness includes a plurality of electric wires, a pair of connectors attached to both end portions of the electric wires, a plurality of exterior members through which the plurality of electric wires are individually inserted, and a plurality of clamps. Each of the exterior members protects the electric wire from, for example, flying objects or water droplets. The plurality of exterior members are fixed to a vehicle body of the vehicle or the like by the clamps. With this configuration, heat generated in the electric wires can be transmitted to the vehicle body having a large surface area via the exterior members and the clamps.

### SUMMARY OF THE INVENTION

In a vehicle, with the electrification of the vehicle, a larger current flows through a wire harness. With this increase in current, it is necessary to take measures against Joule heat generated particularly in a plate-shaped conductor (bus bar) of the wire harness. The wire harness is fixed to a vehicle body for the purpose of heat dissipation. However, in such a case, heat dissipation based on thermal conduction from the plate-shaped conductor of the wire harness to the vehicle body may be insufficient because the vehicle body is generally formed of an iron plate or a steel plate and thus has a relatively small heat capacity.

The disclosure has been made in view of such problems in the related art. Further, an object of the disclosure is to provide a harness heat dissipation structure capable of efficiently dissipating heat generated in a plate-shaped conductor of a wire harness.

A harness heat dissipation structure according to an aspect of the disclosure includes a wire harness that is routed on a vehicle body of a vehicle, and a pressing member that presses the wire harness against the vehicle body, wherein the wire harness includes a plate-shaped conductor having electric conductivity, the plate-shaped conductor has a rectangular cross-sectional shape in a direction orthogonal to a routing direction of the wire harness, and the vehicle body includes a thick portion that is formed thicker than surrounding portions at a location where the pressing member is attached and where the plate-shaped conductor of the wire harness is pressed by the pressing member.

According to the disclosure, it is possible to provide a harness heat dissipation structure capable of efficiently dissipating heat generated in a plate-shaped conductor of a wire harness.

### BRIEF DESCRIPTION OF DRAWINGS

FIG. 1 is a diagram illustrating a schematic configuration of a high-voltage wiring line of an electric vehicle to which the present embodiment is applied.

FIG. 2 is a schematic perspective view illustrating an example of a harness heat dissipation structure according to the present embodiment.

FIG. 3 is a schematic cross-sectional view illustrating an example of the heat dissipation structure according to the present embodiment.

FIG. 4 is a schematic cross-sectional view illustrating a harness heat dissipation structure according to another embodiment.

FIG. 5 is a schematic cross-sectional view illustrating a harness heat dissipation structure according to another embodiment.

FIG. 6 is a schematic cross-sectional view illustrating a harness heat dissipation structure according to another embodiment.

### DETAILED DESCRIPTION OF THE INVENTION

With reference to the drawings, a harness heat dissipation structure according to the present embodiment is described below in detail. Note that the dimensional ratios in the drawings are exaggerated for explanatory purposes, and may differ from the actual ratios.

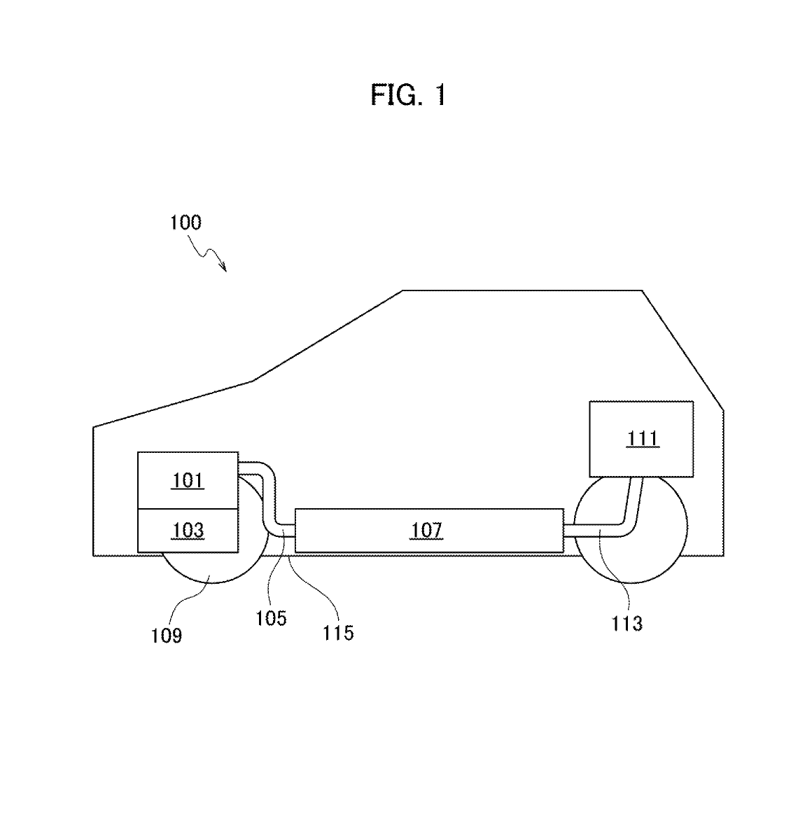

A harness heat dissipation structure 1 according to the present embodiment is applicable to a high-voltage wiring line of an electric vehicle or the like as illustrated in FIG. 1.

As illustrated in FIG. 1, in a vehicle 100, for example, an inverter 101 and a motor 103 serving as load units are arranged on a front side in a vehicle front-rear direction. The inverter 101 is electrically connected to a high-voltage battery 107 via a front-side high-voltage wiring line 105, and converts DC power supplied from the high-voltage battery 107 via the front-side high-voltage wiring line 105 into AC power. Further, the inverter 101 supplies the converted AC power to the motor 103. The motor 103 is driven by the power supplied from the inverter 101, and rotates front wheels 109 via a drive shaft or the like of the vehicle 100.

Further, in the vehicle 100, for example, a charging port 111 is arranged on a rear side in the vehicle front-rear direction. The charging port 111 includes a charging inlet to which an external charging device (omitted in illustration) serving as a charger is connected. The charging port 111 is electrically connected to the high-voltage battery 107 via a rear-side high-voltage wiring 113, and supplies power supplied from the external charging device via the rear-side high-voltage wiring line 113 to the high-voltage battery 107.

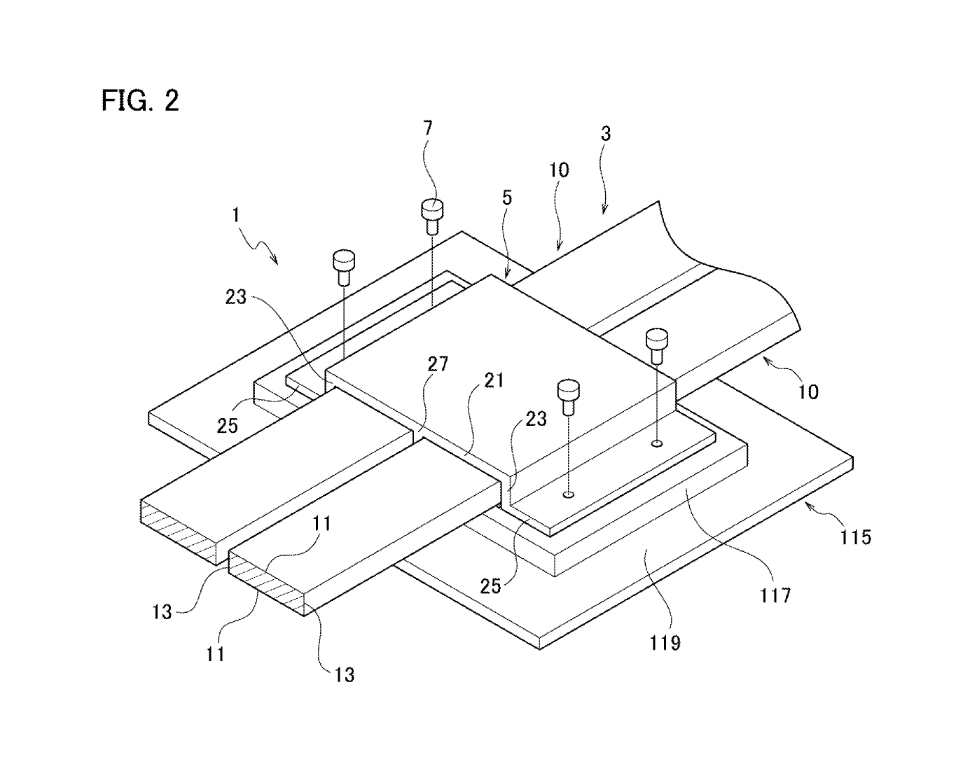

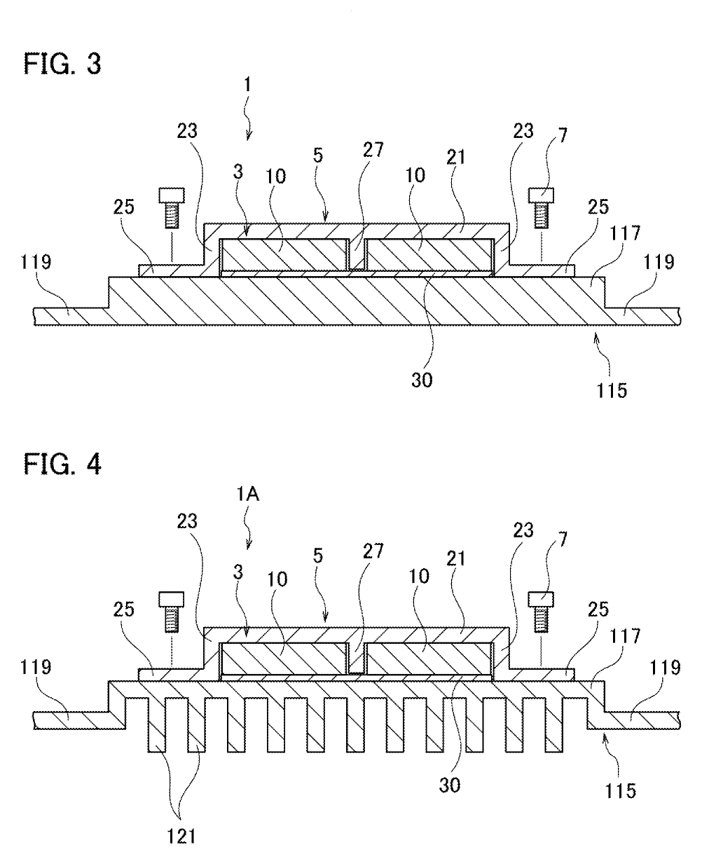

As illustrated in FIGS. 2 and 3, the harness heat dissipation structure 1 according to the present embodiment includes a wire harness 3 and a pressing member 5.

The wire harness 3 is routed on a body panel 115 (see FIG. 1) forming a part of a vehicle body of the vehicle 100. The wire harness 3 includes a bus bar 10 as a plate-shaped conductor having electric conductivity, and the bus bar 10 is formed of a metal material such as copper or aluminum. The wire harness 3 includes a plurality of (in the present embodiment, two) bus bars 10. However, the number of bus bars 10 is not limited thereto, and the wire harness 3 may include a single (one) bus bar 10.

The bus bar 10 has a rectangular cross-sectional shape in a direction orthogonal to a routing direction of the wire harness 3. The bus bar 10 is formed to have a rectangular cross-sectional shape including a pair of long-side surface portions 11 and 11 and a pair of short-side surface portions 13 and 13.

In the present embodiment, the bus bar 10 is arranged to lie laterally so that the pair of long-side surface portions 11 and 11 are parallel to an upper surface of the body panel 115. Thus, an upper surface of the bus bar 10 (one of the pair of long-side surface portions 11 and 11) faces an upper surface portion 21 of the pressing member 5, which is described later, and a lower surface of the bus bar 10 (the other of the pair of long-side surface portions 11 and 11) faces a thick portion 117 of the body panel 115, which is described later.

The pressing member 5 is used to press the wire harness 3 against the body panel 115. The pressing member 5 may be formed of a synthetic resin material, or may be formed of a metal material. In the present embodiment, the pressing member 5 includes the upper surface portion 21 that extends along a direction intersecting with the routing direction of the wire harness 3, and a pair of side surface portions 23 and 23 that extend from both end portions of the upper surface portion 21 in an extending direction thereof toward the thick portion 117 of the body panel 115. Further, the pressing member 5 further includes a pair of flange portions 25 and 25 that extend from lower end portions of the side surface portions 23 in directions away from each other and are coupled to the thick portion 117 by a coupling member such as a bolt 7. In this manner, the pressing member 5 is formed to have a hat-like cross-sectional shape.

Further, at a location of the upper surface portion 21 of the pressing member 5 between the plurality of bus bars 10, a partition wall portion 27 that extends toward the thick portion 117 of the body panel 115 is formed.

The bus bar 10 that is pressed against the body panel 115 is arranged in a space between the upper surface portion 21 and the pair of side surface portions 23 and 23 of the pressing member 5 and the thick portion 117 of the body panel 115.

Further, a heat dissipation sheet 30 as a heat dissipation member having thermal conductivity is arranged between the bus bar 10 and the thick portion 117 of the body panel 115 so that heat generated in the bus bar 10 is efficiently transmitted to the thick portion 117 of the body panel 115. The heat dissipation sheet 30 is also referred to as a thermally conductive sheet, and is arranged in close contact with the bus bar 10 and the thick portion 117 of the body panel 115.

The wire harness 3 and the pressing member 5 are arranged on a vehicle cabin inner side (a floor upper side) of the body panel 115.

The body panel 115 includes the thick portion 117 that is formed thicker than surrounding portions at a location where the pressing member 5 is attached and where the bus bar 10 of the wire harness 3 is pressed by the pressing member 5. A general portion 119 that is thinner than the thick portion 117 is formed around the thick portion 117 of the body panel 115. The thick portion 117 is formed so as to protrude toward the vehicle cabin inner side of the body panel 115. A metal plate forming a part of the thick portion 117 may be attached by welding or the like in addition to the body panel 115 formed of an iron plate or a steel plate. When the body panel 115 is manufactured by casting, the thick portion 117 may be integrally molded with the body panel 115 during casting. In other words, the thick portion 117 may be formed integrally with the body panel 115, or may be formed as a separate body different from the body panel 115 and attached to the body panel 115.

In this manner, the harness heat dissipation structure 1 according to an aspect of the present embodiment includes the wire harness 3 that is routed on the vehicle body (the body panel 115) of the vehicle 100, and the pressing member 5 that presses the wire harness 3 against the vehicle body (the body panel 115). The wire harness 3 includes the plate-shaped conductor (the bus bar 10) having electric conductivity, and the plate-shaped conductor (the bus bar 10) has a rectangular cross-sectional shape in the direction orthogonal to the routing direction of the wire harness 3. The vehicle body (the body panel 115) includes the thick portion 117 that is formed thicker than the surrounding portions at the location where the pressing member 5 is attached and where the plate-shaped conductor (the bus bar 10) of the wire harness 3 is pressed by the pressing member 5.

The pressing member 5 is used to press the bus bar 10 against the body panel 115. With this, Joule heat generated in the bus bar 10 can be transmitted to the body panel 115 and dissipated, and a temperature rise at the wire harness 3 can be suppressed. Thus, an increase in size of the components (particularly, the bus bar 10) forming the wire harness 3 for suppressing heat generation in the wire harness 3 can be avoided, and weight reduction of the wire harness 3 and reduction of manufacturing cost can be achieved.

Further, at the location of the body panel 115 against which the bus bar 10 is pressed by the pressing member 5, the thick portion 117 is formed. With this, the heat capacity of the body panel 115 can be increased. Further, a temperature rise at the wire harness 3 can be suppressed, or a temperature rise can be delayed. Thus, an increase in size of the components (particularly, the bus bar 10) forming the wire harness 3 for suppressing heat generation in the wire harness 3 can be avoided, and weight reduction of the wire harness 3 and reduction of manufacturing cost can be achieved.

As described above, according to the present embodiment, it is possible to provide the harness heat dissipation structure 1 capable of efficiently dissipating heat generated in the plate-shaped conductor (the bus bar 10) of the wire harness 3.

In the harness heat dissipation structure 1, the heat dissipation member (the heat dissipation sheet 30) having thermal conductivity may be arranged between the plate-shaped conductor (the bus bar 10) and the thick portion 117 of the vehicle body (the body panel 115).

The heat dissipation sheet 30 is arranged at a portion of the bus bar 10 that contacts with the body panel 115. With this, the gap between the bus bar 10 and the body panel 115 can be filled, and heat can be efficiently transmitted from the bus bar 10 to the body panel 115.

In the harness heat dissipation structure 1, the pressing member 5 may include the upper surface portion 21 that extend along the direction intersecting with the routing direction of the wire harness 3, and the pair of side surface portions 23 and 23 that extend from both the end portions of the upper surface portion 21 in the extending direction thereof toward the thick portion 117 of the vehicle body (the body panel 115). The pressing member 5 may further include the pair of flange portions 25 and 25 that extend from the lower end portions of the side surface portions 23 in the directions away from each other and are coupled to the thick portion 117, and thus may be formed to have a hat-like cross-sectional shape. The plate-shaped conductor (the bus bar 10) that is pressed against the vehicle body (the body panel 115) may be arranged in the space between the upper surface portion 21 and the pair of side surface portions 23 and 23 of the pressing member 5 and the thick portion 117 of the vehicle body (the body panel 115).

By using the pressing member 5 formed to have a hat-like cross-sectional shape, the bus bar 10 is pressed against the body panel 115. With this, heat generated in the bus bar 10 can be transmitted sufficiently to the body panel 115, and heat dissipation performance by the harness heat dissipation structure 1 can be improved.

### OTHER EMBODIMENTS

With reference to FIGS. 4-6, harness heat dissipation structures 1A, 1B, and 1C according to other embodiments are described below. Note that components that are substantially the same as those of the harness heat dissipation structure 1 described above are denoted by the same reference symbols, and descriptions thereof are omitted.

As illustrated in FIG. 4, in the harness heat dissipation structure 1A, a plurality of heat dissipation fins 121 are formed at a location where the thick portion 117 of the body panel 115 is formed on a vehicle cabin outer side (a floor lower side). the shape and the attachment direction of the heat dissipation fin 121 may be set so that air heated by thermal conduction from the bus bar 10 is prevented from stagnating between the plurality of heat dissipation fins 121. A metal material forming the heat dissipation fin 121 may be attached by welding or the like in addition to the body panel 115 formed of an iron plate or a steel plate. When the body panel 115 is manufactured by casting, the heat dissipation fin 121 may be integrally molded with the body panel 115 during casting. In other words, the heat dissipation fin 121 may be formed integrally with the body panel 115, or may be formed as a separate body different from the body panel 115 and attached to the body panel 115.

As described above, in the harness heat dissipation structure 1A, the wire harness 3 and the pressing member 5 may be arranged on the cabin inner side (the floor upper side) of the vehicle body (the body panel 115). At a location where the thick portion 117 of the vehicle body (the body panel 115) is formed on the vehicle cabin outer side (the floor lower side), the heat dissipation fin 121 may be formed.

On the back surface of the attachment surface of the bus bar 10 of the body panel 115, the heat dissipation fin 121 is formed, and a portion (an area surface) of the body panel 115 that contacts with external air is increased. With this, heat dissipation performance by the harness heat dissipation structure 1 can be improved.

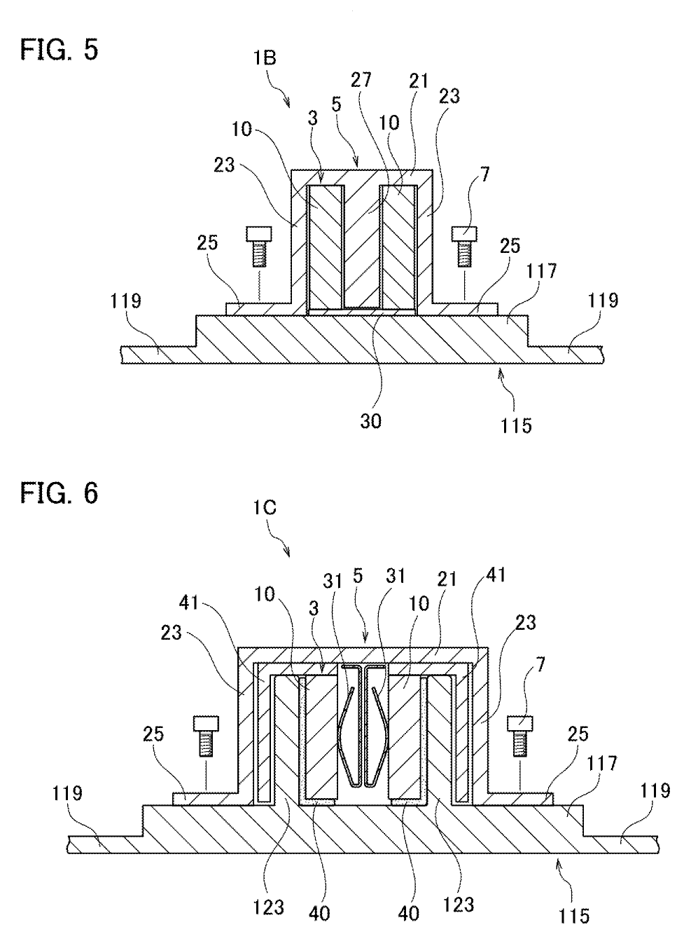

As illustrated in FIG. 5, in the harness heat dissipation structure 1B, the bus bar 10 is arranged to stand so as to be perpendicular to the body panel 115. Thus, an upper surface of the bus bar 10 (one of the pair of short-side surface portions 13 and 13) faces the upper surface portion 21 of the pressing member 5, which is described later, and a lower surface of the bus bar 10 (the other of the pair of short-side surface portions 13 and 13) faces the thick portion 117 of the body panel 115.

As described above, in the harness heat dissipation structure 1B, the plate-shaped conductor (the bus bar 10) may be arranged to stand so as to be perpendicular to the vehicle body (the body panel 115).

Depending on a mounting requirement of the wire harness 3 to the vehicle 100, as illustrated in FIG. 5, mounting may be performed while the bus bar 10 is arranged with its longitudinal direction standing upright. Even in such a case, heat generated in the bus bar 10 can be efficiently transmitted to the thick portion 117 of the body panel 115.

As illustrated in FIG. 6, in the harness heat dissipation structure 1C, a rib portion 123 as a wall portion that stands perpendicular to the body panel 115 is formed at the thick portion 117 of the body panel 115, and the bus bar 10 is pressed against the rib portion 123 by a spring member 31. Thus, one side surface of the bus bar 10 (one of the pair of long-side surface portions 11 and 11) faces the rib portion 123 of the body panel 115, and the other side surface of the bus bar 10 (the other of the pair of long-side surface portions 11 and 11) faces the spring member 31. Further, a thermally conductive member 40 is arranged as a heat dissipation member having thermal conductivity between the bus bar 10 and the thick portion 117 of the body panel 115 and between the bus bar 10 and the rib portion 123 of the body panel 115. The thermally conductive member 40 is used so as to efficiently transmit heat generated in the bus bar 10 to the thick portion 117 and the rib portion 123 of the body panel 115, and is formed of thermal paste, a thermally conductive resin, or the like. Further, in the harness heat dissipation structure 1C, a case 41 having an L-like cross-sectional shape is used mainly for holding the bus bar 10 when the pressing member 5 is attached to the body panel 115. The case 41 is formed of, for example, a synthetic resin material.

As described above, in the harness heat dissipation structure 1C, at the thick portion 117 of the vehicle body (the body panel 115), the wall portion (the rib portion 123) that stands perpendicular to the vehicle body (the body panel 115) may be formed. The plate-shaped conductor (the bus bar 10) may be pressed against the wall portion (the rib portion 123) by the spring member 31.

As illustrated in FIG. 5, when mounting is performed while the bus bar 10 is arranged with its longitudinal direction standing upright, only the short-side surface portion 13 of the bus bar 10 faces the thick portion 117. Thus, it is predicted that a heat dissipation effect is lower as compared to a case where the long-side surface portion 11 of the bus bar 10 faces the thick portion 117. Thus, as illustrated in FIG. 6, the rib portion 123 is formed at the thick portion 117 of the body panel 115, and the bus bar 10 is pressed against the rib portion 123 by the spring member 31. With this, an heat dissipation effect can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A harness heat dissipation structure comprising:
a wire harness that is routed on a vehicle body of a vehicle; and
a pressing member that presses the wire harness against the vehicle body, wherein
the wire harness includes a plate-shaped conductor having electric conductivity,
the plate-shaped conductor has a rectangular cross-sectional shape in a direction orthogonal to a routing direction of the wire harness,
the vehicle body includes a thick portion that is formed thicker than surrounding portions at a location where the pressing member is attached and where the plate-shaped conductor of the wire harness is pressed by the pressing member,
the thick portion is formed integrally with the vehicle body, and
the pressing member is coupled to the thick portion by a coupling member.

2. The harness heat dissipation structure according to claim 1, wherein
a heat dissipation member having thermal conductivity is arranged between the plate-shaped conductor and the thick portion of the vehicle body.

3. The harness heat dissipation structure according to claim 1, wherein
the wire harness and the pressing member are arranged on a vehicle cabin inner side of the vehicle body, and
a heat dissipation fin is formed on a vehicle cabin outer side of the vehicle body at a location where the thick portion is formed.

4. The harness heat dissipation structure according to claim 1, wherein
the plate-shaped conductor is arranged to stand so as to be perpendicular to the vehicle body.

5. The harness heat dissipation structure according to claim 4, wherein
a wall portion that stands perpendicular to the vehicle body is formed on the thick portion of the vehicle body, and
the plate-shaped conductor is pressed against the wall portion by a spring member.

6. The harness heat dissipation structure according to claim 1, wherein
the pressing member is formed to have a hat-like cross-sectional shape, and includes:
an upper surface portion that extends along a direction intersecting with the routing direction of the wire harness;
a pair of side surface portions that extend from both end portions of the upper surface portion in an extending direction thereof toward the thick portion of the vehicle body;
a pair of flange portions that extend from lower end portions of the side surface portions in directions away from each other and are coupled to the thick portion, and
the plate-shaped conductor that is pressed against the vehicle body is arranged in a space surrounded by the upper surface portion and the pair of side surface portions of the pressing member and the thick portion of the vehicle body.
